(19) United States
(12) Patent Application Publication
(10) Pub. No.: US 2009/0140791 A1
(43) Pub. Date: Jun. 4, 2009

(54) Switching Element Control

(76) Inventor: Paul D. Young, El Cajon, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 12/251,673

(22) Filed: Oct. 15, 2008

Related U.S. Application Data
(60) Provisional application No. 61/004,717, filed on Nov. 29, 2007.

(51) Int. Cl. H03K 17/56

(52) U.S. Cl. 327/419

(57) ABSTRACT

An apparatus in an example comprises a switching element and diode-resistor coupling. The diode-resistor coupling controls timing characteristics of turn ON and turn OFF of the switching element.

This application claims the benefit of U.S. provisional patent application Ser. No. 61/004,717, filed on Nov. 29, 2007, entitled “SWITCHING ELEMENT CONTROL”.

### BACKGROUND

Field Effect Transistors (FETs), Bipolar Junction Transistors (BJTs), or other switching elements may be used such as for controlling power. Examples of circuits that use switching elements to control power comprise Switched-Mode Power Supplies (SMPS), motor controllers, and lighting ballasts. Multiple switching elements may be used in an alternating topology such as to switch power in totem-pole, push-pull, and full-bridge configurations.

The signal controlling a switching element is usually a clock, or a derivative of a clock. The control signal serves to drive the switching element, for example, the gate of a FET. The control signals for switching multiple elements in a circuit topology can have relatively fast switching times.

### DESCRIPTION OF THE DRAWINGS

Features of exemplary embodiments will become apparent from the description, the claims, and the accompanying drawings in which:

FIG. 1 is a representation of an embodiment of an apparatus that comprises one or more diode-resistor couplings, one or more switching elements, one or more source controllers, one or more capacitors, one or more resistors, one or more diodes, a ground, one or more interface connections, and a load.

FIG. 2 is a representation of another embodiment that comprises a subset of the components of the apparatus of FIG. 1.

FIG. 3 is an exemplary plot of three traces of voltage versus time of one of the switching elements of an embodiment of the apparatus of FIG. 1 and illustrates that by presence of the respective diode-resistor coupling a delay is provided between activation of a source voltage signal from the source controller by one of the traces going high and turn ON of the switching element by one of the traces going low.

FIG. 4 represents a plot in contrast to the plot of FIG. 3 and illustrates relatively little or minimal delay is provided by omission of the respective diode-resistor coupling between activation of a source voltage signal from a source controller by a trace going high and turn ON of a switching element by a trace going low.

FIG. 5 is similar to FIG. 3 and illustrates that with presence of the diode-resistor coupling relatively little or minimal delay is provided between deactivation of the source voltage signal from the source controller by the trace going low and turn OFF of the switching element by the trace going high.

FIG. 6 is an exemplary plot of traces of voltage versus time of outputs of a plurality of switching elements of an embodiment of the apparatus of FIG. 1 and illustrates that presence of a respective plurality of diode-resistor couplings ensures non-overlap of turn ON of the plurality of switching elements.

FIG. 7 represents a plot in contrast to the plot of FIG. 6 and illustrates overlap of turn ON for switching elements is provided by omission of respective diode-resistor couplings.

### DETAILED DESCRIPTION

Referring to the BACKGROUND section above, in a number of circuit configurations a need exists to prevent two or more switching elements as power control elements from being turned ON simultaneously to allow correct and/or proper operation. Where simultaneous turn ON is to be prevented for correct circuit operation, even brief periods of turn-on overlap in the switching elements can be problematic. One result could be increased, excessive, undesirable, and/or massive current flow through the switching elements. A switching element could be immediately damaged or deteriorated to a point of latent failure. Further, the controller that provides the control signal to the switching elements could fail.

For use as a power control element, a switching element that comprises a Field Effect Transistor (FET) or Bipolar Junction Transistors (BJT) may be intended to be switched completely ON and then completely OFF. An upstream controller for the power control element may operate toward turning one switching element ON before another switching element has been turned OFF. Multiple switching elements may be used in an alternating current (AC) topology such as to switch power in totem-pole, push-pull, and full-bridge configurations.

An embodiment comprises an AC coupled switching element drive, for example, a FET drive, to promote fail-safe operation. An embodiment comprises an AC coupling scheme for driving power switching elements, for example, FETs, for power supplies, motor controllers, or other power applications, for example, to prevent catastrophic damage during fault conditions.

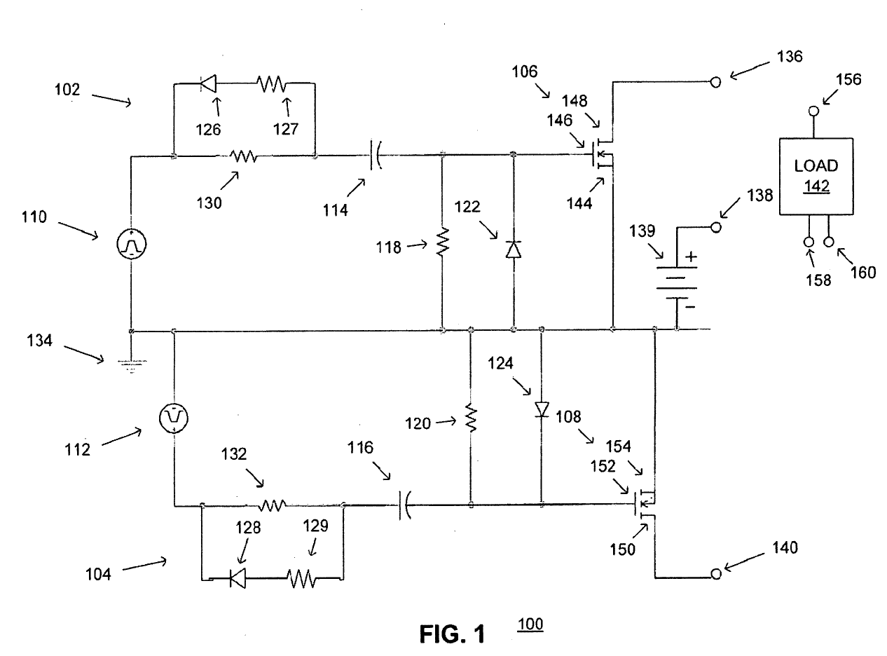

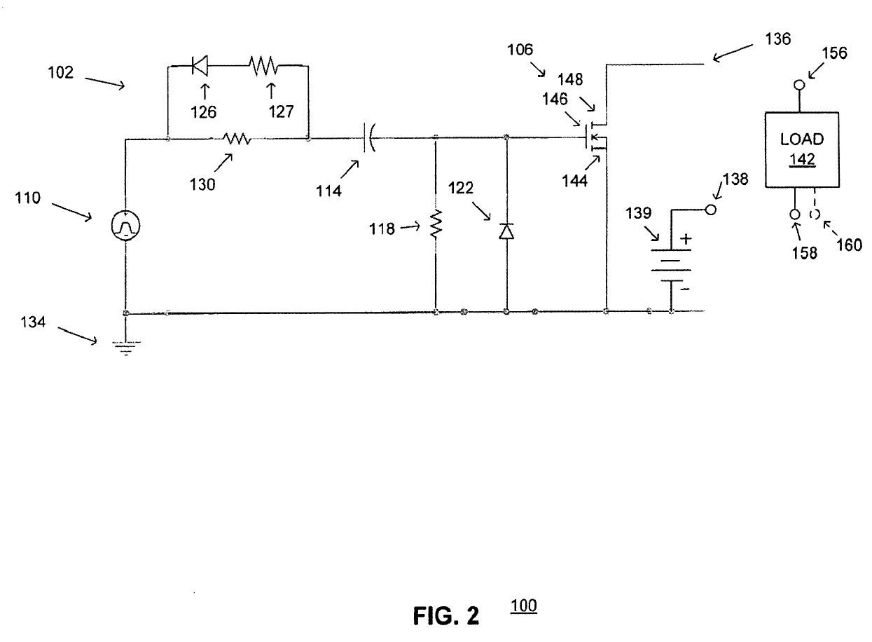

Turning to FIGS. 1 and 2, an embodiment of an apparatus 100 comprises one or more diode-resistor couplings 102, 104, one or more switching elements 106, 108, one or more source controllers 110, 112, one or more capacitors 114, 116, one or more resistors 118, 120, one or more diodes 122, 124, a ground 134, one or more interface connections 136, 138, 140, a voltage source power supply 139, and a load 142. Referring to FIG. 1, the diode-resistor couplings 102, 104 comprise diodes 126, 128 and resistors 127, 129, 130, 132. The resistors 127, 129 in an example are optional, as described herein. Where employed, the resistors 127, 129 may allow independent control of turn OFF time of the switching elements 106 and 108. The resistors 130, 132 may serve to control the turn ON time of the switching elements 106, 108, and the resistors 127 and 129 may serve to define the turn OFF times of the switching elements 106, 108. A lower value of resistance serves to cause a decrease in time, whether turn OFF or turn ON. A lower value of resistance of the resistors 130, 132 serves to decrease the turn ON time of the switching elements 106, 108. A lower value of resistance of the resistors 127, 129 serves to decrease the turn OFF time of the switching elements 106, 108. By presence of the diode-resistor coupling 102, 104 in an example a delay is provided between activation of a source voltage signal from the voltage source power supply 139 and turn ON of the switching element 106, 108. With presence of the diode-resistor coupling 102, 104 in an example relatively little delay is provided between deactivation of the source voltage signal from the voltage source power supply 139 and turn OFF of the switching element 106, 108.

The interface connections 136, 138, 140 serve to couple an output device as the load 142 such as a transformer. Referring to FIG. 2, the interface connections 136, 138 serve to couple an output device as the load 142 such as a transformer, as will be appreciated by those skilled in the art. The load 142 in an example comprises one or more interface connections 156, 158, 160. Referring to FIG. 1, the interface connections 136, 138, 140 may couple with the interface connections 156, 158, 160, respectively. Referring to FIG. 2, the interface connections 136, 138 in an example may couple with the interface connections 156, 158, respectively. The interface connection 160 for the load 142 may or may not be present, and if so, may or may not couple with the ground 134, as will be appreciated by those skilled in the art.

The switching elements 106, 108 in an example comprise FETs or BJTs. Referring to FIGS. 1 and 2, a FET as the switching element 106 comprises source 144, gate 146, and drain 148, for example, as an output. Referring to FIG. 1, a FET as the switching element 108 comprises source 150, gate 152, and drain 154, for example, as an output.

Referring to FIGS. 1 and 2, the diode-resistor coupling 102 controls timing characteristics of turn ON and turn OFF of the switching element 106 by power from the source controller 110. Referring to FIG. 1, the diode-resistor coupling 104 controls timing characteristics of turn ON and turn OFF of the switching element 108 by power from the source controller 112.

Referring to FIGS. 1 and 2, the resistor 130 of the diode-resistor coupling 102 provides a selected, intended, and/or relatively small delay on a turn ON such as from resistance of the diode-resistor coupling 102 and the gate capacitance inherent in a FET as the switching element 106. Referring to FIG. 1, the resistor 132 of the diode-resistor coupling 104 provides a selected, intended, and/or relatively small delay such as from delay from resistance of the diode-resistor coupling 104 and the gate capacitance inherent in a FET as the switching element 108. Exemplary delays of turn ON range from ten (10) nSec to one (1) μSec inclusively; from 20 (twenty) nSec to 1 (one) μSec inclusively; from 50 (fifty) nSec to 1 (one) μSec inclusively; from fifty (50) nSec to 500 (five hundred) nSec inclusively; and/or from 100 (one hundred) nSec to 500 (five hundred) nSec inclusively. The delay serves to slow down a turn ON of the FETs as the switching elements 106 and 108.

On a turn OFF of the FETs as the switching elements 106 and 108 the diodes 126 and 128, respectively, and the resistors 127 and 129, respectively, provide and/or promote a more rapid turn OFF, for example, due to lower or much lower resistance values of for the resistors 127, 129 relative to 130, 132, respectively. Another embodiment omits the resistors 127, 129 and instead substitutes direct connections to the diodes 126, 128 to promote a most rapid turn OFF. Exemplary values of the resistors 130, 132 comprise ten (10) to ten thousand (10,000) ohms; ten (10) to four thousand (4,000) ohms; ten (10) to one thousand (1,000) ohms; and/or ten (10) to four hundred (400) ohms. Exemplary values of the resistors 127, 129 comprise zero (0) to ten thousand (10,000) ohms; zero (0) to four thousand (4,000) ohms; zero (0) to one thousand (1,000) ohms; and/or zero (0) to four hundred (400) ohms, for example, when the resistors 127, 129 are present.

Referring to FIGS. 1 and 2, on a turn OFF of the FET as the switching element 106, the diode 126 bypasses the resistor 130 and instead passes the turn OFF control signal through resistor 127. Referring to FIG. 1, on a turn OFF of the FET as the switching element 108, the diode 128 bypasses the resistor 132 and instead passes the turn OFF control signal through resistor 129. Exemplary rapidity of turn OFF ranges from ten (10) nSec to two (2) μSec inclusively; from twenty (20) nSec to two (2) μSec inclusively; from fifty (50) nSec to one (1) μSec inclusively; and/or from one hundred (100) nSec to one (1) μSec inclusively.

A combination of slow turn ON and rapid turn OFF serves to promote avoidance of both FETs as the switching elements 106, 108 from being ON at the same time. A dead time exists when both switching elements 106, 108 are turned OFF. Exemplary dead-time intervals may range from ten (10) nSec to one (1) μSec inclusively; twenty (20) nSec to one (1) μSec inclusively; 50 (fifty) nSec to 500 (five hundred) nSec inclusively; and/or one hundred (100) nSec to five hundred (500) nSec inclusively, for example, depending on switching frequency and component tolerances and variations. In another embodiment, the direction of the diodes 126, 128 could be reversed, or the value of the resistors 127, 129 could be larger than the value of the resistors 130, 132 respectively, to have a fast turn ON and a slow turn OFF, as will be appreciated by those skilled in the art.

An illustrative description of an exemplary operation of an embodiment of the apparatus 100 is presented, for explanatory purposes. The source controllers 110, 112 provide control signals, for example, an alternating current such as a square wave. It may be desirable to avoid too much voltage flowing to the switching element 106, 108 such as upon failure of the source controller 110, 112 in continuing to supply activation voltage as a source to the switching elements 106, 108.

The capacitor 114 blocks direct current so the voltage from the source controller 110 would not continue to the switching element 106 in a failed condition of the source controller 110. The resistor 118 would bleed off the voltage from the capacitor 114. The diode 122 restores the voltage to the switching element 106 from the source controller 110 during normal operation. The diode 122 keeps the voltage positive into the gate of the FET as the switching element 106. The capacitor 114 and the resistor 118 center the voltage from the source controller 110 about the ground 134, so the voltage into the switching element 106 goes between positive and negative voltage in the waveform. The diode 122 keeps the negative voltage from going to the gate of the FET as the switching element 106. In an event of failure of the source controller 110, the resistor 118 would bleed off the voltage through the resistor 118 so the switching element 106 will turn OFF rather than be left continuously turned ON.

The resistor 130 slows down the turn ON of the switching element 106. The resistor softens the turn ON of the switching element 106. The diode 126 bypasses a slowdown of turn OFF that the resistor 130 may otherwise provide, for example, employing instead a lower resistance value of the resistor 127. The switching element 106 is turned ON slowly and turned OFF quickly. In another embodiment, the direction of the diodes 126, 128 could be reversed, or the value of the resistors 127, 129 could be larger than the value of the resistors 130, 132 respectively, to have a fast turn ON and a slow turn OFF.

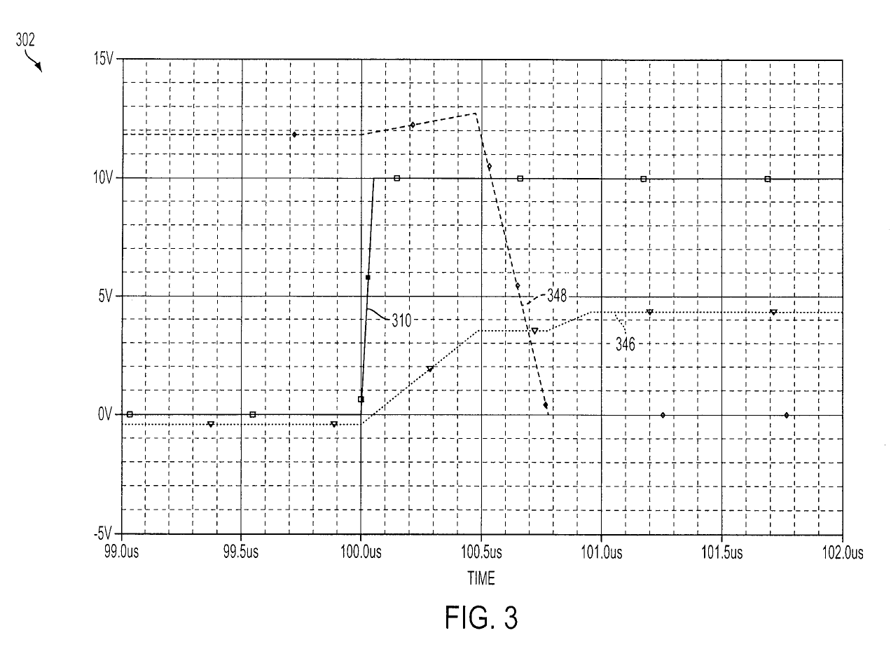

FIG. 3 is an exemplary plot 302 that comprises traces 310, 346, 348. The trace 310 in an example corresponds to a source voltage signal from the source controller 110. In a further example, the trace 310 corresponds to a source voltage signal from the source controller 112. The trace 346 in an example corresponds to the gate 146 of an FET as the switching element 106. In a further example, the trace 346 corresponds to the gate 152 of an FET as the switching element 108. The trace 348 in an example corresponds to the drain 148 as an output of the FET as the switching element 106. In a further example, the trace 348 corresponds to the drain 154 as an output of the FET as the switching element 108. By presence of the diode-resistor coupling 102, 104, a delay is provided between activation of the source voltage signal from the source controller 110, 112, respectively, by the trace 310 going high and turn ON of the switching element 106, 108, respectively, by the trace 348 going low. Exemplary delays of turn ON range from ten (10) nSec to one (1) μSec inclusively; from 20 (twenty) nSec to 1 (one) μSec inclusively; from 50 (fifty) nSec to 1 (one) μSec inclusively; from fifty (50) nSec to 500 (five hundred) nSec inclusively; and/or from 100 (one hundred) nSec to 500 (five hundred) nSec inclusively. The delay serves to slow down a turn ON of the FETs as the switching elements 106 and 108.

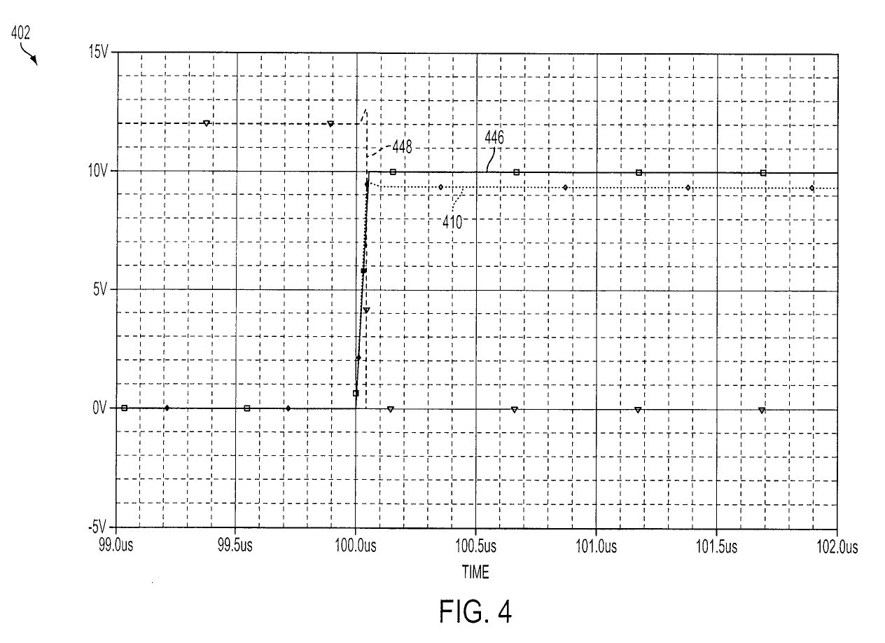

In contrast to the plot 302 of FIG. 3, plot 402 of FIG. 4 with traces 410, 446, 448 illustrates relatively little or minimal delay is provided by omission of the respective diode-resistor coupling 102, 104 between activation of a source voltage signal from a source controller in isolation analogous to the source controller 110, 112 by the trace 410 going high and turn ON of a switching element in isolation analogous to the switching element 106, 108 by the trace 448 going low. The trace 410 in an example corresponds to a source voltage signal from a source controller in isolation analogous to the source controller 110, 112. The trace 446 in an example corresponds to a gate of an FET in isolation analogous to the gate 146, 152 of an FET as the switching element 106, 108. The trace 448 in an example corresponds to a drain as an output of a FET in isolation analogous to the drain 148, 154 as an output of the FET as the switching element 106, 108.

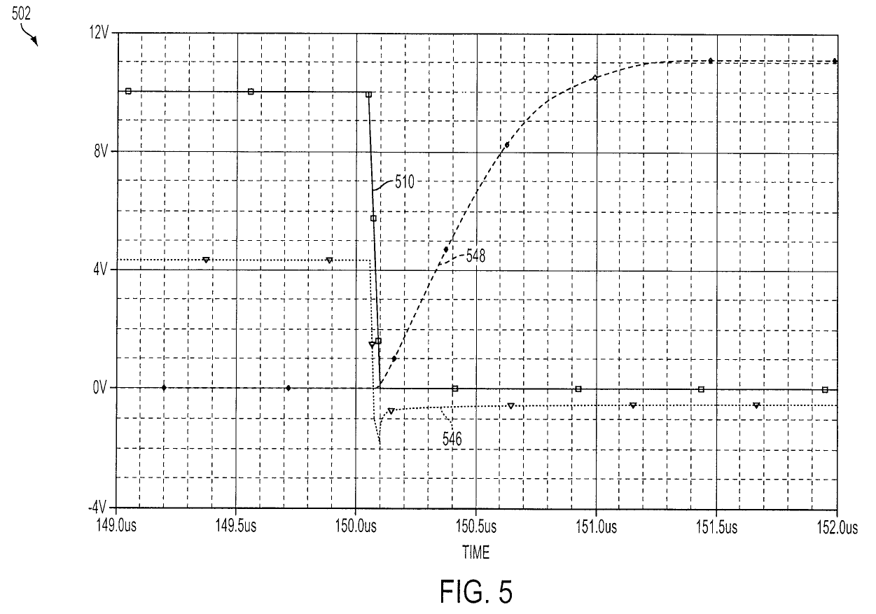

FIG. 5 is an exemplary plot 502 that comprises traces 510, 546, 548. The trace 510 in an example corresponds to a source voltage signal from the source controller 110. In a further example, the trace 510 corresponds to a source voltage signal from the source controller 112. The trace 546 in an example corresponds to the gate 146 of an FET as the switching element 106. In a further example, the trace 546 corresponds to the gate 152 of an FET as the switching element 108. The trace 548 in an example corresponds to the drain 148 as an output of the FET as the switching element 106. In a further example, the trace 548 corresponds to the drain 154 as an output of the FET as the switching element 108. With presence of the diode-resistor coupling 102, 104, relatively little or minimal delay is provided analogous to omission of the respective diode-resistor coupling 102, 104 between deactivation of the source voltage signal from the source controller 110, 112, respectively, by the trace 510 going low and turn OFF of the switching element 106, 108, respectively, by the trace 548 going high. Referring to FIGS. 1 and 2, on a turn OFF of the FET as the switching element 106 the diode 126 bypasses the resistor 130, and instead employs a lower value resistance in the resistor 127. Referring to FIG. 1, on a turn OFF of the FET as the switching element 108 the diode 128 bypasses the resistor 132, for example, employing instead a lower resistance value of the resistor 129. Exemplary rapidity of turn OFF ranges from ten (10) nSec to two (2) μSec inclusively. In a further example, rapidity of turn OFF ranges from one hundred (100) nSec to two (2) μSec inclusively. The plots 546 and 548 in FIG. 5 correspond to values for resistors 127 and 129 of zero (0) ohms. The turn OFF times will be increased with increasing resistance values for the resistors 127, 129, as will be appreciated by those skilled in the art.

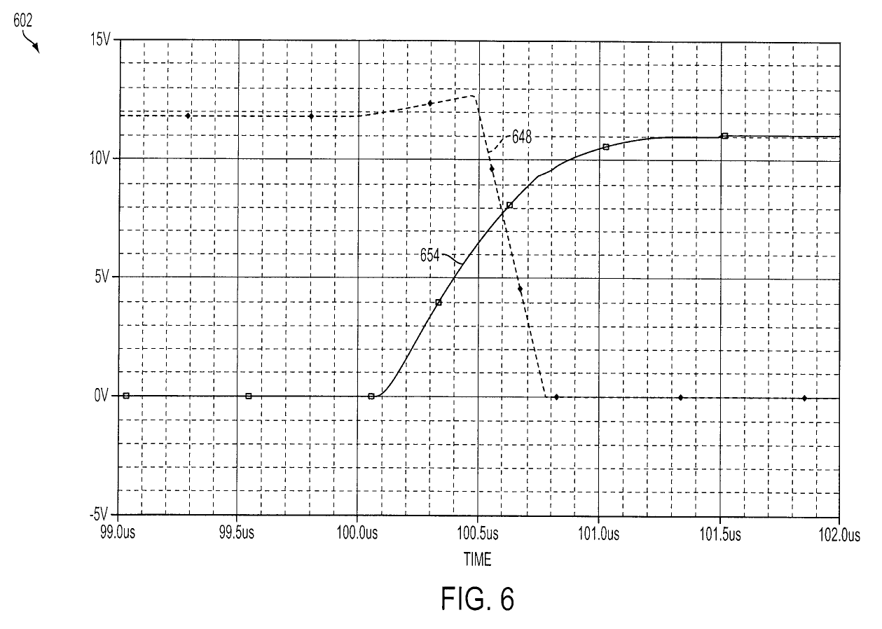

FIG. 6 is an exemplary plot 602 that comprises traces 648, 654. The trace 648 corresponds to the drain 148 as an output of the FET as the switching element 106. The trace 654 corresponds to the drain 154 as an output of the FET as the switching element 108. The trace 648 for the switching element 106 turns ON by going to low voltage after the trace 654 for the switching element 108 turns OFF. The sequence of the trace 648 going low after the trace 654 goes high represents non-overlap of turn ON for both the switching elements 106, 108. The dead-time interval exists when both switching elements 106, 108 are turned OFF. Exemplary dead-time intervals may range from ten (10) nSec to one (1) μSec inclusively; twenty (20) nSec to one (1) μSec inclusively; 50 (fifty) nSec to 500 (five hundred) nSec inclusively; and/or one hundred (100) nSec to five hundred (500) nSec inclusively, for example, depending on switching frequency and component tolerances and variations. The diode-resistor couplings 102, 104 serve to ensure non-overlap of turn ON of a plurality of switching elements 106, 108. The traces 648, 654 demonstrate non-overlap of turn ON for both the switching elements 106, 108. The plot 654 in FIG. 6 corresponds to values for resistors 127 and 129 of zero (0) ohms. The turn OFF time will be increased with increasing resistance values for the resistors 127, 129, as will be appreciated by those skilled in the art.

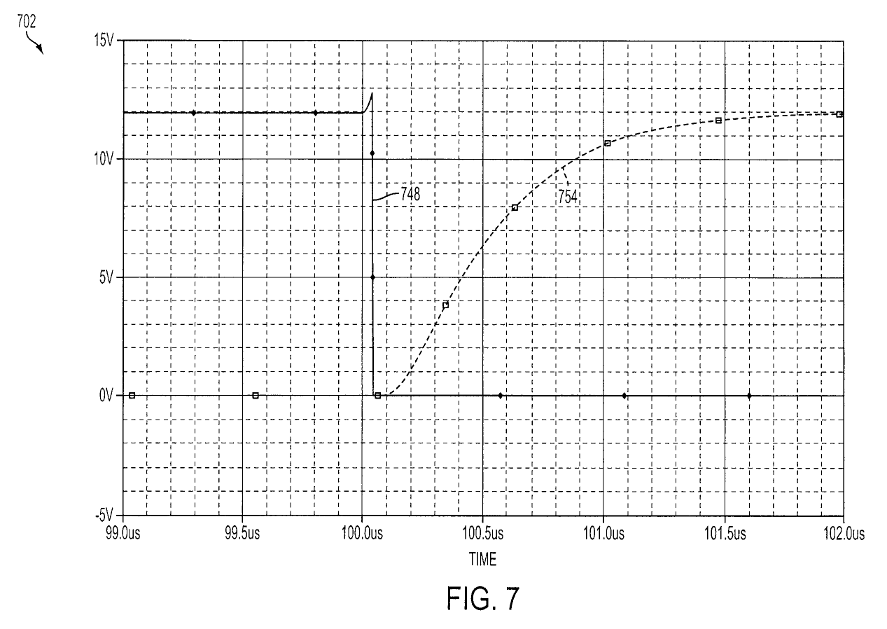

In contrast to the plot 602 of FIG. 6, plot 702 of FIG. 7 with traces 748, 754 illustrates overlap of turn ON for switching elements in isolation analogous to the switching elements 106, 108 is provided by omission of the respective diode-resistor couplings 102, 104. Both the traces 748, 754 go low and turn ON for a same interval of time. The trace 748 corresponds to a drain as an output of a FET in isolation analogous to the drain 148 as an output of the FET as the switching element 106. The trace 754 corresponds to a drain as an output of a FET in isolation analogous to the drain 154 as an output of the FET as the switching element 108.

An embodiment of the apparatus 100 comprises a plurality of components such as one or more of electronic components, chemical components, organic components, mechanical components, hardware components, optical components, and/or computer software components. A number of such components can be combined or divided in an embodiment of the apparatus 100. In one or more exemplary embodiments, one or more features described herein in connection with one or more components and/or one or more parts thereof are applicable and/or extendible analogously to one or more other instances of the particular component and/or other components in the apparatus 100. In one or more exemplary embodiments, one or more features described herein in connection with one or more components and/or one or more parts thereof may be omitted from or modified in one or more other instances of the particular component and/or other components in the apparatus 100. An exemplary technical effect is one or more exemplary and/or desirable functions, approaches, and/or procedures. An exemplary component of an embodiment of the apparatus 100 employs and/or comprises a set and/or series of computer instructions written in or implemented with any of a number of programming languages, as will be appreciated by those skilled in the art. An embodiment of the apparatus 100 comprises any (e.g., horizontal, oblique, angled, or vertical) orientation, with the description and figures herein illustrating an exemplary orientation of an exemplary embodiment of the apparatus 100, for explanatory purposes.

The steps or operations described herein are examples. There may be variations to these steps or operations without departing from the spirit of the invention. For example, the steps may be performed in a differing order, or steps may be added, deleted, or modified.

Although exemplary embodiment of the invention has been depicted and described in detail herein, it will be apparent to those skilled in the relevant art that various modifications, additions, substitutions, and the like can be made without departing from the spirit of the invention and these are therefore considered to be within the scope of the invention as defined in the following claims.

What is claimed is:

1. An apparatus, comprising:
a switching element; and
diode-resistor coupling that controls timing characteristics of turn ON and turn OFF of the switching element.

2. The apparatus of claim 1, wherein the diode-resistor coupling comprises a single resistor and a single diode coupled in parallel.

3. The apparatus of claim 1, wherein the diode-resistor coupling comprises a parallel coupling of:
a single diode and a first single resistor coupled in series; and
a second single resistor.

4. The apparatus of claim 3, wherein the second single resistor slows turn ON of the switching element.

5. The apparatus of claim 4, wherein the single diode and the first single resistor coupled in series bypass the second single resistor to promote rapid turn OFF of the switching element.

6. The apparatus of claim 1, wherein the diode-resistor coupling controls power from a source controller to control the timing characteristics of turn ON and turn OFF of the switching element.

7. The apparatus of claim 1, wherein the diode-resistor coupling comprises a resistor that slows turn ON of the switching element.

8. The apparatus of claim 7, wherein the diode-resistor coupling comprises a diode that bypasses the resistor for turn OFF of the switching element.

9. The apparatus of claim 1, wherein by presence of the diode-resistor coupling a delay is provided between activation of a source voltage signal and turn ON of the switching element.

10. The apparatus of claim 9, wherein by presence of the diode-resistor coupling the delay from activation of the source voltage signal to turn ON of the switching element is between ten (10) nSec and one (1) μSec inclusively.

11. The apparatus of claim 1, wherein the diode-resistor coupling comprises a diode that promotes rapid turn OFF of the switching element.

12. The apparatus of claim 1, wherein with presence of the diode-resistor coupling relatively little delay is provided between deactivation of a source voltage signal and turn OFF of the switching element.

13. The apparatus of claim 12, wherein with presence of the diode-resistor coupling the relatively little delay from deactivation of the source voltage signal to turn OFF of the switching element is between ten (10) nSec and two (2) μSec inclusively.

14. The apparatus of claim 1, wherein the switching element comprises a first switching element, wherein the diode-resistor coupling comprises a first diode-resistor coupling, the apparatus further comprising:
a second switching element; and
a second diode-resistor coupling that controls timing characteristics of turn ON and turn OFF of the second switching element;
wherein the first and second diode-resistor couplings serve to ensure non-overlap of turn ON of the first and second switching elements.

15. The apparatus of claim 14, wherein a combination of relatively slow turn ON and relatively rapid turn OFF for the first and second switching elements serves to promote avoidance of the first and second switching elements being turned ON at a same time.

16. The apparatus of claim 15, wherein a dead time exists when the first and second switching elements are turned OFF at a same time during active operation.

17. The apparatus of claim 16, wherein the dead time when the first and second switching elements are turned OFF at the same time during active operation is between ten (10) nSec and one (1) μSec inclusively.

18. The apparatus of claim 14, wherein a combination of relatively rapid turn ON and relatively slow turn OFF for the first and second switching elements serves to promote avoidance of the first and second switching elements being turned OFF at a same time.

19. An apparatus, comprising:
means for ensuring non-overlap of turn ON of a plurality of switching elements through reliance on a respective plurality of diode-resistor couplings.

20. A method, comprising the step of:
ensuring non-overlap of turn ON of a plurality of switching elements through reliance on a respective plurality of diode-resistor couplings.
